(19) United States
(12) Patent Application Publication
(10) Pub. No.: US 2014/0374778 A1
(43) Pub. Date: Dec. 25, 2014

(54) Optical Assembly

(71) Applicant: Robert Bosch GmbH, Stuttgart (DE)

(72) Inventors: Richard Fix, Gerlingen (DE); Patrick Sonstroem, Herrenberg (DE)

(21) Appl. No.: 14/310,032

(22) Filed: Jun. 20, 2014

(30) Foreign Application Priority Data
Jun. 20, 2013 (DE) 10 2013 211 595.4

(51) Int. Cl. H01L 33/08; H01L 31/167

(52) U.S. Cl. CPC H01L 33/08; H01L 31/167
USPC 257/85; 257/90

(57) ABSTRACT

An optical assembly configured to emit electromagnetic radiation comprises first and second electroluminescent semiconductor components positioned adjacent to each other. The first electroluminescent semiconductor component is transparent to electromagnetic radiation generated by the second electroluminescent semiconductor component, and the second electroluminescent semiconductor component is transparent to electromagnetic radiation generated by the first electroluminescent semiconductor component. The first electroluminescent semiconductor component and the second electroluminescent semiconductor component are configured to actuate independently of each other.

This application claims priority under 35 U.S.C. §119 to patent application no. DE 10 2013 211 595.4, filed on Jun. 20, 2013 in Germany, the disclosure of which is incorporated herein by reference in its entirety.

### BACKGROUND

Optical assemblies are used for various purposes for emitting electromagnetic radiation. By way of example, optical assemblies can be used in the field of optical sensor technology.

The laid-open application DE 101 12 542 A1 has disclosed a radiation-emitting optical assembly which comprises an active layer configured for electroluminescence and a passive layer configured for photoluminescence.

The laid-open application DE 10 2006 010 727 A1 has disclosed a semiconductor component with at least two active regions configured for electroluminescence, with the active regions being connected to one another in an electrically conductive manner and embodied for generating radiation with the same wavelength.

Optical assemblies with such a design have a very compact embodiment, which is advantageous in the course of a desired miniaturization of electronically operated assemblies.

### SUMMARY

The subject matter of the disclosure relates to an optical assembly for emitting electromagnetic radiation, comprising at least two semiconductor components configured for electroluminescence, with, of two semiconductor components arranged adjacent to one another, at least one semiconductor component being embodied to be transparent to the electromagnetic radiation generatable by the respective other semiconductor component by electroluminescence, characterized in that the semiconductor components can be actuated independently from one another.

In particular, the semiconductor components are therefore actuatable independently of one another since they are not connected to one another in an electrically conductive manner. An advantage of this is that the intensity and type of the electromagnetic radiation that can be emitted by an optical assembly according to the disclosure can be controlled in a targeted and very exact manner.

The electromagnetic radiation generated by the individual semiconductor components preferably leaves the optical assembly at the same place on the optical assembly. The electromagnetic radiation from said semiconductor components thus overlaps provided that it is emitted simultaneously.

Depending on the technical requirements, the optical assembly may also comprise three or more semiconductor components configured for electroluminescence.

According to an advantageous configuration, the semiconductor components differ from one another in terms of the emission wavelengths of the electromagnetic radiation respectively generatable thereby by electroluminescence, with, of two semiconductor components arranged adjacent to one another, the semiconductor component whose electromagnetic radiation has an emission wavelength which is shorter than the emission wavelength of the respectively other semiconductor component being embodied to be transparent to the electromagnetic radiation from the other semiconductor component. As a result of this, it is possible to switch to-and-fro between different emission wavelengths, for example by means of a pulsed operation of the individual semiconductor components.

According to a further advantageous configuration, the optical assembly comprises at least one substrate body with an arrangement side, on which the semiconductor components are arranged, with the semiconductor components being arranged in series with respect to one another in relation to a surface normal of the arrangement side. As a result of this, it is possible to define a beam path aligned parallel to the surface normal of the arrangement side of the substrate body. Here, the electromagnetic radiation generated by at least one semiconductor component can be guided through at least one further semiconductor component.

A further advantageous configuration provides for the substrate body to be embodied to be transparent to the electromagnetic radiation generated by the semiconductor components, with the electromagnetic radiation generated by the semiconductor components emerging from the optical assembly through the substrate body and with the semiconductor component which generates electromagnetic radiation with the shortest emission wavelength being arranged closest to the substrate body. Such an optical assembly is also referred to as substrate emitter.

In the case of a transparent configuration of substrate bodies, two or more optical assemblies can also be combined structurally in such a way that the electromagnetic radiation emitted by one optical assembly passes through at least one further optical assembly and emerges from the latter together with the electromagnetic radiation emitted by the latter optical assembly.

Furthermore, it is considered to be advantageous if the semiconductor component generating electromagnetic radiation with the longest emission wavelength is arranged closest to the substrate body, with the electromagnetic radiation generated by the semiconductor components emerging from the optical assembly through the semiconductor component which generates electromagnetic radiation with the shortest emission wavelength or through at least one layer arranged at this semiconductor component, with the layer being arranged on the side of the semiconductor component facing away from the substrate body and being embodied to be at least partly transparent to the electromagnetic radiation generated by the semiconductor components. The layer can be embodied as a protective layer. In this embodiment, the substrate body can be embodied to be partly or completely opaque to the electromagnetic radiation generated by the semiconductor components.

According to a further advantageous configuration, the optical assembly comprises at least one compensation layer arranged between two semiconductor components arranged adjacent to one another, which compensation layer is embodied to be transparent to the electromagnetic radiation from at least one of the two semiconductor components adjoining it. By way of example, by arranging a compensation layer it is possible to minimize tensions between individual semiconductor components which are caused e.g. by different lattice constants of the materials used for the semiconductor components. The more the emission wavelengths generated by the individual semiconductor components differ, the more advantageous the arrangement of a compensation layer between the semiconductor components becomes.

The subject matter of the disclosure moreover relates to an optical arrangement for emitting electromagnetic radiation, comprising at least one optical assembly and at least one optical lens, characterized in that the optical assembly is embodied according to one of the above-described configurations or any combination of same, with electromagnetic radiation emitted by the optical assembly extending through the optical lens. This is linked to the advantages specified above in relation to the optical assembly. The optical lens can be embodied for focusing or dispersing the electromagnetic radiation generated by the optical assembly.

In the case of conventional optical arrangements, at least two semiconductor components generating electromagnetic radiation are arranged next to one another with respect to the respective beam path, with the beam path emerging from each semiconductor component being routed through a separate optical lens. Hence, conventionally, there must be at least two optical lenses. In contrast thereto, an optical arrangement according to the disclosure allows the electromagnetic radiation emitted by the optical assembly to be influenced as desired by means of a single optical lens, independently of the number of semiconductor components configured for electroluminescence. This is accompanied by a reduction in the number of components and saving of costs when producing corresponding optical arrangements.

According to one advantageous configuration, the optical arrangement comprises at least one optical fiber, with it being possible for electromagnetic radiation emitted by the optical assembly to be coupled into the optical fiber through the optical lens. In the case of conventional optical arrangements, at least two semiconductor components generating electromagnetic radiation are arranged next to one another with respect to the respective beam paths, with the beam path emerging from each semiconductor component being routed through a separate optical lens and a separate optical fiber. Hence, conventionally, there must also be at least two optical fibers. In contrast thereto, the advantageous embodiment of the optical arrangement allows the electromagnetic radiation emitted by the optical assembly to be forwarded by means of a single optical fiber, independently of the number of semiconductor components configured for electroluminescence. This is accompanied by a reduction in the number of components and saving of costs when producing corresponding optical arrangements.

Moreover, it is known for the conventionally present multiplicity of optical fibers to be connected to a single optical fiber by means of an optical fiber coupler. However, part of the electromagnetic radiation coupled into the optical fiber couplers is usually lost therein. In the optical arrangement according to the disclosure it is possible to dispense with optical fiber couplers, and so corresponding losses do not occur.

The subject matter of the disclosure furthermore relates to an optical system, comprising at least one optical assembly, by means of which electromagnetic radiation can be emitted, and at least one optical detector apparatus, by means of which electromagnetic radiation emitted by the optical assembly can be detected, characterized in that the optical assembly is embodied according to one of the above-described configurations or any combination of same. This is linked to the advantages specified above in relation to the optical assembly.

The optical system can be used for detecting substances in gases and/or liquids. By way of example, the optical system can be used as an exhaust-gas sensor. Furthermore, the optical system can be used, for example, for detecting substances contained in a fluid in medical engineering applications, in respiratory gas analysis, in fire detection, in lab-on-a-chip applications, in ventilation installations, in controlling the climate and in appliances found in consumer electronics, such as e.g. in smartphones, in games consoles or the like.

The optical system advantageously comprises an electronic control apparatus controlling the optical assembly, with it being possible for the semiconductor components of the optical assembly to be actuated independently of one another by means of the electronic control apparatus.

In the following text, the disclosure will be explained in an exemplary manner on the basis of preferred exemplary embodiments, with reference being made to the attached figures, wherein the features illustrated below can represent an aspect of the disclosure, both on their own and combined in various combinations.

### BRIEF DESCRIPTION OF THE DRAWINGS

FIG. 1 shows a schematic illustration of an exemplary embodiment of an optical assembly according to the disclosure,

FIG. 2 shows a schematic illustration of a further exemplary embodiment of an optical assembly according to the disclosure,

FIG. 3 shows a schematic illustration of an exemplary embodiment of an optical arrangement according to the disclosure, and

FIG. 4 shows a schematic illustration of an exemplary embodiment of an optical system according to the disclosure.

### DETAILED DESCRIPTION

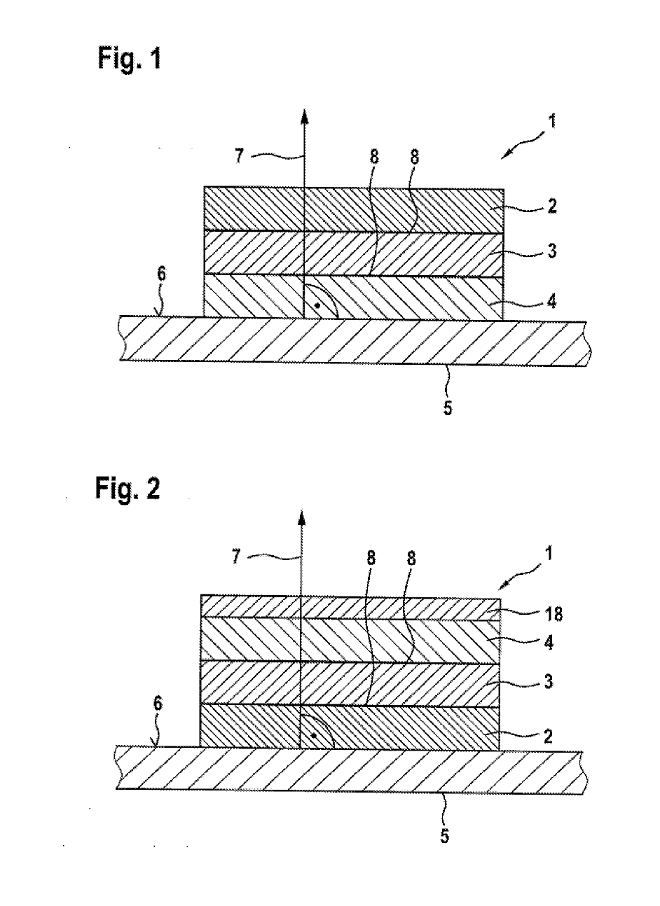

FIG. 1 shows an optical assembly 1 for emitting electromagnetic radiation, in a first exemplary embodiment. The optical assembly 1 comprises three semiconductor components 2, 3 and 4 configured for electroluminescence. Moreover, the optical assembly 1 comprises a substrate body 5 with an arrangement side 6, on which the semiconductor components 2, 3 and 4 are arranged. The semiconductor components 2, 3 and 4 are arranged in series with respect to one another in relation to a surface normal 7 of the arrangement side 6. The semiconductor components 2, 3 and 4 can be actuated independently of one another.

The substrate body 5 is embodied to be transparent to the electromagnetic radiation generated by the semiconductor components 2, 3 and 4, with the electromagnetic radiation generated by the semiconductor components 2, 3 and 4 emerging from the optical assembly 1 through the substrate body 5.

The semiconductor components 2, 3 and 4 differ from one another in terms of the emission wavelengths of the electromagnetic radiation respectively generatable thereby by electroluminescence. The semiconductor component 4 generates electromagnetic radiation with the shortest emission wavelength and is arranged closest to the substrate body 5. The semiconductor component 3 generates electromagnetic radiation with an emission wavelength that is longer than the emission wavelength generated by the semiconductor component 4. The semiconductor component 2 generates electromagnetic radiation with an emission wavelength that is longer than the emission wavelength generated by the semiconductor component 3.

The semiconductor component 3 is embodied to be transparent to the electromagnetic radiation generatable by the semiconductor component 2 by electroluminescence. The semiconductor component 4 is embodied to be transparent to the electromagnetic radiation generatable by the semiconductor components 2 and 3 by electroluminescence.

A compensation layer 8 is arranged in each case between two semiconductor components 2 and 3, and also 3 and 4, arranged adjacent to one another. The compensation layer 8 arranged between the semiconductor components 2 and 3 is embodied to be transparent to the electromagnetic radiation generated by the semiconductor component 2. The compensation layer 8 arranged between the semiconductor components 3 and 4 is embodied to be transparent to the electromagnetic radiation generated by the semiconductor components 2 and 3.

FIG. 2 shows a schematic illustration of a further exemplary embodiment of an optical assembly 1 according to the disclosure. In contrast to the exemplary embodiment shown in FIG. 1, the substrate body 5 in FIG. 2 is embodied to be opaque to the electromagnetic radiation generated by the semiconductor components 2, 3 and 4. Moreover, the semiconductor components 2, 3 and 4, and the compensation layers 8 arranged therebetween, are arranged in a reverse order, with the semiconductor component 2, which generates electromagnetic radiation with the longest emission wavelength, being arranged closest to the substrate 5. The electromagnetic radiations generated by the semiconductor components 2, 3 and 4 emerge from the optical assembly 1 through a layer 18 arranged on the semiconductor component 4, which generates electromagnetic radiation with the shortest emission wavelength. The layer 18 is arranged on the side of the semiconductor component 4 facing away from the substrate body 5 and embodied to be at least partly transparent to the electromagnetic radiations generated by the semiconductor components 2, 3 and 4.

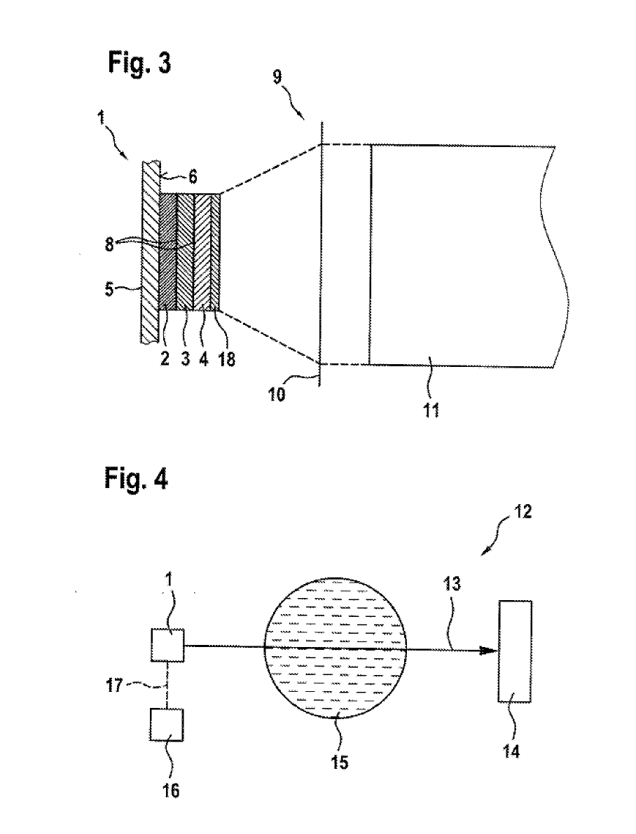

FIG. 3 shows a schematic illustration of an exemplary embodiment of an optical arrangement 9 according to the disclosure, for emitting electromagnetic radiation. The optical arrangement 9 has an optical assembly 1, which is embodied in accordance with the optical assembly 1 shown in FIG. 2. Moreover, the optical arrangement 9 comprises a convex optical lens 10 and an optical fiber 11. Electromagnetic radiation emitted by the optical assembly 9 can be coupled into the optical fiber 11 through the optical lens 10.

FIG. 4 shows a schematic illustration of an exemplary embodiment of an optical system 12 according to the disclosure. The optical system 12 comprises an optical assembly 1, which is merely depicted schematically in FIG. 4 and by means of which electromagnetic radiation can be emitted; this is intended to be indicated by the arrow 13. The optical system 12 furthermore comprises an optical detector apparatus 14, by means of which the electromagnetic radiation emitted by the optical assembly 1 can be detected. The electromagnetic radiation generated by the optical assembly 1 passes through a gaseous or liquid fluid 15 along its path to the optical detector apparatus 14. If substances whose absorption bands overlap with the emission spectrum of the optical assembly 1 are present in the fluid 15, there is absorption of the respective electromagnetic radiation, which can be registered by means of the optical detector apparatus 14. The optical system 12 furthermore comprises an electronic control apparatus 16 controlling the optical assembly 1, by means of which electronic control apparatus the semiconductor components 2, 3 and 4 of the optical assembly 1 can be actuated independently from one another. To this end, the electronic control apparatus 16 is linked to the optical assembly 1 by means of a connection 17.

What is claimed is:

1. An optical assembly configured to emit electromagnetic radiation, comprising:
a first electroluminescent semiconductor component; and
a second electroluminescent semiconductor component positioned adjacent to the first electroluminescent semiconductor component,
wherein the first electroluminescent semiconductor component is transparent to electromagnetic radiation generated by the second electroluminescent semiconductor component;
wherein the second electroluminescent semiconductor component is transparent to electromagnetic radiation generated by the first electroluminescent semiconductor component; and
wherein the first electroluminescent semiconductor component and the second electroluminescent semiconductor component are configured to actuate independently of each other.

2. The optical assembly according to claim 1, wherein:
the first electroluminescent semiconductor component generates electromagnetic radiation having a first emission wavelength;
the second electroluminescent semiconductor component generates electromagnetic radiation having a second emission wavelength; and
the first emission wavelength is shorter than the second emission wavelength.

3. The optical assembly according to claim 2, further comprising:
at least one substrate body defining an arrangement side,
wherein the first electroluminescent semiconductor component and the second electroluminescent semiconductor component are positioned in series with respect to each other in relation to a surface normal of the arrangement side of the at least one substrate body.

4. The optical assembly according to claim 3, wherein:
the at least one substrate body is transparent to electromagnetic radiation generated by the first electroluminescent semiconductor component and the second electroluminescent semiconductor component;
electromagnetic radiation generated by the first electroluminescent semiconductor component and the second electroluminescent semiconductor component emerges from the optical assembly through the at least one substrate body; and
wherein the first electroluminescent semiconductor component is positioned closer to the at least one substrate body than the second electroluminescent semiconductor component.

5. The optical assembly according to claim 3, wherein:
the second electroluminescent semiconductor component is positioned closer to the substrate body than the first electroluminescent semiconductor component;
electromagnetic radiation generated by the first electroluminescent semiconductor component emerges from the optical assembly directly from the first electroluminescent semiconductor component or through at least one layer positioned on a side of the first electroluminescent semiconductor component facing away from the substrate body; and
the at least one layer is at least partly transparent to electromagnetic radiation generated by the first electroluminescent semiconductor component and the second electroluminescent semiconductor component.

6. The optical assembly according to claim 1, further comprising:
at least one compensation layer positioned between the first electroluminescent semiconductor component and the second electroluminescent semiconductor component,
wherein the at least one compensation layer is transparent to electromagnetic radiation generated by at least one of the first electroluminescent semiconductor component and the second electroluminescent semiconductor component.

7. An optical arrangement configured to emit electromagnetic radiation, comprising:
at least one optical lens; and
at least one optical assembly, including:
a first electroluminescent semiconductor component; and
a second electroluminescent semiconductor component positioned adjacent to the first electroluminescent semiconductor component,
wherein the first electroluminescent semiconductor component is transparent to electromagnetic radiation generated by the second electroluminescent semiconductor component;
wherein the second electroluminescent semiconductor component is transparent to electromagnetic radiation generated by the first electroluminescent semiconductor component; and
wherein the first electroluminescent semiconductor component and the second electroluminescent semiconductor component are configured to actuate independently of each other,
wherein electromagnetic radiation generated by the first electroluminescent semiconductor component and the second electroluminescent semiconductor component is emitted through the at least one optical lens.

8. The optical arrangement according to claim 7, further comprising:
at least one optical fiber,
wherein electromagnetic radiation generated by the first electroluminescent semiconductor component and the second electroluminescent semiconductor component is coupled into the optical fiber through the optical lens.

9. An optical system, comprising:
at least one optical assembly configured to emit electromagnetic radiation, including:
a first electroluminescent semiconductor component; and
a second electroluminescent semiconductor component positioned adjacent to the first electroluminescent semiconductor component,
wherein the first electroluminescent semiconductor component is transparent to electromagnetic radiation generated by the second electroluminescent semiconductor component;
wherein the second electroluminescent semiconductor component is transparent to electromagnetic radiation generated by the first electroluminescent semiconductor component; and
wherein the first electroluminescent semiconductor component and the second electroluminescent semiconductor component are configured to actuate independently of each other, and
at least one optical detector apparatus configured to detect electromagnetic radiation emitted by the optical assembly.

10. The optical system according to claim 9, further comprising:
an electronic control apparatus configured to control the optical assembly, and further configured to actuate the first electroluminescent semiconductor component and the second electroluminescent semiconductor component independently of each other.
